(19) United States
(12) Patent Application Publication
(10) Pub. No.: US 2007/0045000 A1
(43) Pub. Date: Mar. 1, 2007

(54) MULTILAYER PRINTED CIRCUIT BOARD

(75) Inventors: YU-HSU LIN, San Jose, CA (US); SHANG-TSANG YEH, TU CHENG (TW); CHAO-CHEN HUANG, TU CHENG (TW); CHUAN-BING LI, SHENZHEN (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., TU CHENG (TW)

(21) Appl. No.: 11/308,755

(22) Filed: Apr. 28, 2006

(30) Foreign Application Priority Data
Aug. 12, 2005 (CN) 200510036574.5

(51) Int. Cl. H05K 1/11

(52) U.S. Cl. 174/264

(57) ABSTRACT

A printed circuit board includes improved via for improving signal integrity. The printed circuit board includes a first layer, a second layer, a third layer and a via. The via includes a drill hole, a first pad and a second pad. The first pad is defined in the first layer, and the second pad is defined in the second layer. The drill hole is transversely defined through the first layer and the second layer. A void is defined in the third layer corresponding to the second pad. The PCB attenuates signal reflection when the signal is transmitted through the via improving signal integrity.

### FIELD OF THE INVENTION

The present invention relates to printed circuit boards, and particularly to a multilayer printed circuit board that can improve signal integrity.

### DESCRIPTION OF RELATED ART

Multilayer printed circuit boards (PCBs) are commonly used in electronic devices to connect electronic components such as integrated circuits to one another. A typical multilayer PCB includes many layers of copper, with each layer of copper separated by a dielectric material. Generally, several of the copper layers are used to provide a reference voltage plane or ground plane. In addition, several layers of the copper are etched to form the traces that connect individual components. Vias in a multilayer PCB provide layer-to-layer interconnections. Copper lined through-vias extend though the layers of the PCB to selectively connect the electronic components on the surface of the PCB to the reference planes and traces within the PCB and to selectively connect copper traces on different layers to one another.

Referring to FIG. 5, an 8-layer printed circuit board is provided. The printed circuit board 30 includes a first layer 31, a second layer 32, a third layer 33, and a buried via 34. The buried via 34 includes a first pad 310, a second pad 330, and a drill hole 35 providing an electrical connection between the first layer 31 and the third layer 33. The first layer 31 and the third layer 33 are signal layers, the second layer 32 is a reference layer which can be a power layer or a ground layer. The first pad 310 is formed in the first layer 31, and the second pad 330 is formed in the third layer 33. The drill hole 35 passes through the first layer 31, the second layer 32, and the third layer 33. An annular antipad 321 is formed in the second layer 32 around the drill hole 35 for insulating the drill hole 35 from the second layer 32. A parasitic capacitance is generated between the pad 310 and its adjacent layer and the pad 330 and its adjacent layer. The parasitic capacitance prolongs rise time of a signal, and causes distortion in transmitted signals. The parasitic capacitance has a big impact on trace impedance. When signals are transmitted through the via 34, signal reflection may occur because of the parasitic capacitance.

It is therefore apparent that a need exits to provide a multilayer PCB that can attenuate signal reflection when the signal is transmitted through the vias.

### SUMMARY OF THE INVENTION

An exemplary printed circuit board includes improved vias for improving signal integrity. The printed circuit board includes a first layer, a second layer, a third layer, and a via. The via includes a drill hole, a first pad, and a second pad. The first pad is defined in the first layer, and the second pad is defined in the second layer. The drill hole is transversely defined through the first layer and the second layer. An void is defined in the third layer corresponding to the second pad. The PCB attenuates signal reflection when the signal is transmitted through the via for improved signal integrity.

Other advantages and novel features will become more apparent from the following detailed description when taken in conjunction with the accompanying drawings, in which:

### BRIEF DESCRIPTION OF THE DRAWINGS

FIG. 1 is a sectional view of a printed circuit board (PCB) in accordance with a first preferred embodiment of the preset invention;

FIG. 2 is a graph showing impedance waveforms obtained using the PCBs of FIG. 1 and FIG. 5;

FIG. 3 is a graph showing reflection waveforms obtained using the PCBs of FIG. 1 and FIG. 5;

FIG. 4 is a sectional view of a printed circuit board in accordance with a second preferred embodiment of the preset invention; and

FIG. 5 is a sectional view of a conventional PCB.

### DETAILED DESCRIPTION OF THE INVENTION

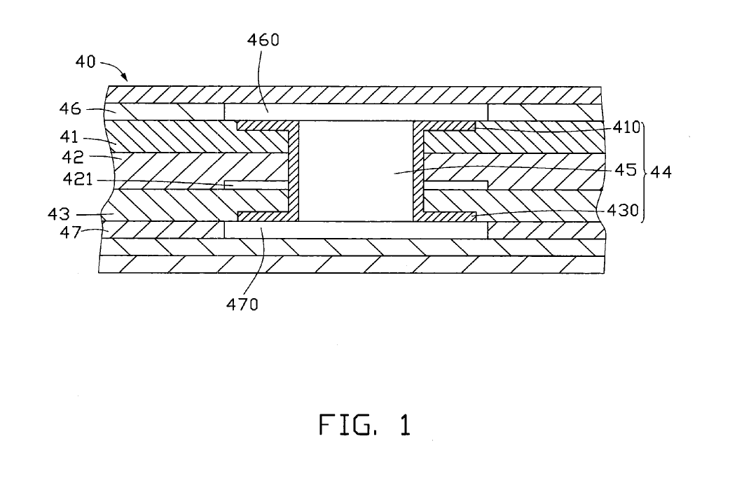

Referring to FIG. 1, a printed circuit board (PCB) 40 according to a first embodiment of the present invention is provided. The PCB 40 is an 8-layer printed circuit board. The printed circuit board 40 includes a first layer 41, a second layer 42, a third layer 43, a fourth layer 46, a fifth layer 47, and a buried via 44. The buried via 44 includes a first pad 410, a second pad 430, and a drill hole 45 lined with a conductive material providing an electrical connection between the first layer 41 and the third layer 43. The first layer 41 and the third layer 43 are signal layers, the second layer 42, the fourth layer 46, and the fifth layer 47 are reference layers which can be any one of a power layer or a ground layer. The first pad 410 is formed in the first layer 41, and the second pad 430 is formed in the third layer 43. The drill hole 45 passes through the first layer 41, the second layer 42, and the third layer 43. An annular antipad 421 is formed in the second layer 42 around the drill hole 45 for insulating the drill hole 45 from the second layer 42. An void 460 is defined in the fourth layer 46 over the pad 410, and an void 470 is defined in the fifth layer 47 underneath the pad 430.

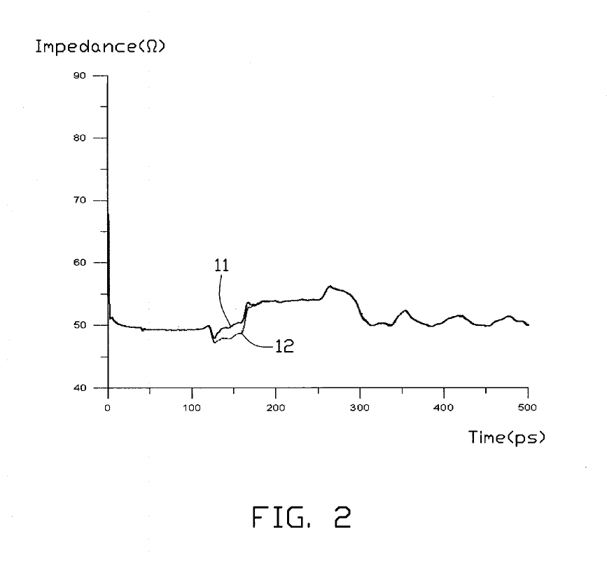

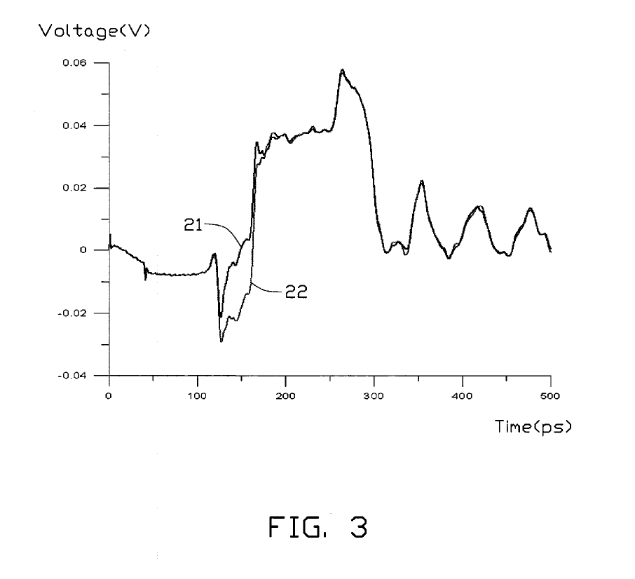

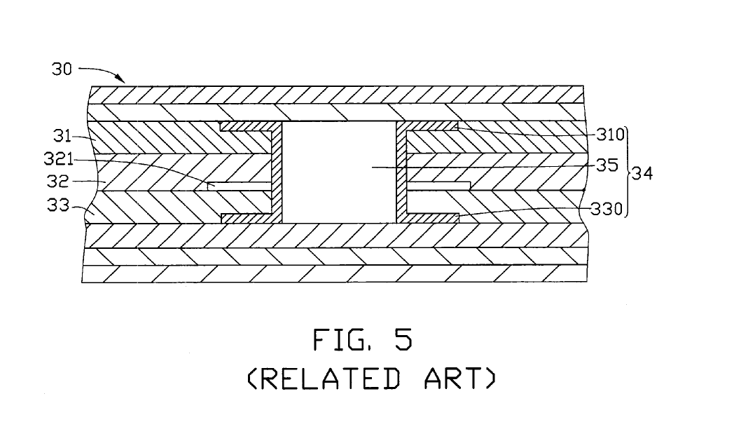

FIGS. 2 and 3 are comparative graphs showing impedance and reflection waveforms obtained using the PCB of FIG. 1 and a conventional PCB shown in FIG. 5. In FIG. 2, from 100 picoseconds (ps) to 200 ps, a signal is transmitted through the via 44. Curve 11 denotes an impedance waveform obtained using the PCB of FIG. 1, curve 12 denotes an impedance waveform obtained using the PCB of FIG. 5. As shown in FIG. 2, when the signal is transmitted through the via 44, the curve 11 has a more gentle slope than curve 12. Further, as shown in FIG. 3, with curve 21 denoting a reflection waveform obtained using the PCB of FIG. 1, 22 denoting a reflection waveform obtained using the PCB of FIG. 5, it can be seen that curve 21 has a more gentle slope than curve 22. The use of the voids 460, 470 between a top of pad 410 and a next layer, and between the bottom of the pad 430 and another next layer, improves signal integrity of signals transmitted through the via 44.

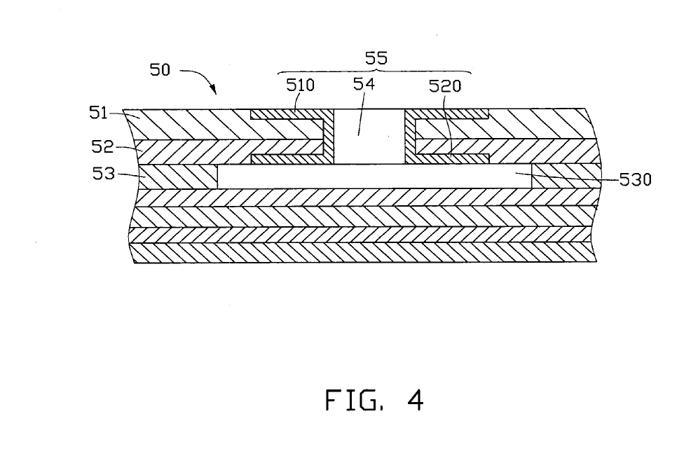

Referring to FIG. 4, a printed circuit board 50 in accordance with a second preferred embodiment of the present invention is shown. The printed circuit board 50 includes a first layer 51, a second layer 52, a third layer 53, and a blind via 54. The blind via 54 includes a first pad 510, a second pad 520, and a drill hole 54 providing an electrical connection between the first layer 51 and the second layer 52. The first layer 51 and the second layer 52 are signal layers, the third layer 53 is a reference layer which can be any one of a power layer or ground layer. The first pad 510 is formed in the first layer 51, and the second pad 520 is formed in the second layer 52. The drill hole 54 passes through the first layer 51 and the second layer 52. Avoid 530 is defined in the third layer 53 underneath the pad 520 to reduce wave reflection when a signal is transmitted through the via 54.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A printed circuit board (PCB) comprising:
a via comprising a drill hole, a first pad, and a second pad;
a first layer with the first pad formed therein;
a second layer with the second pad formed therein, the drill hole being lined with a conducting material, the conducting material providing an electrical connection between the first layer and the second layer; and
a third layer adjacent the second layer, and having a void defined therein corresponding to the second pad.

2. The PCB as claimed in claim 1, wherein the via is a blind via.

3. The PCB as claimed in claim 2, wherein the first layer is adjacent the second layer.

4. The PCB as claimed in claim 3, wherein the first layer and the second layer are signal layers, and the third layer is any one of a power layer or a ground layer.

5. The PCB as claimed in claim 1, wherein the via is a buried via.

6. The PCB as claimed in claim 1, wherein a fourth layer is stacked between the first layer and the second layer, the drill hole passes through the first, second, and fourth layers, an annular antipad is formed in the fourth layer around the drill hole for insulating the drill hole from the fourth layer.

7. The PCB as claimed in claim 6, wherein a fifth layer is stacked adjacent the first layer, a void is defined in the fifth layer corresponding to the first pad.

8. The PCB as claimed in claim 7, wherein the first and second layers are signal layers, and the third, fourth, and fifth layers are any one of a power layer and a ground layer.

9. A method for improving signal integrity of a printed circuit board (PCB) comprising steps of:
providing a first layer with a first pad formed therein;
providing a second layer with a second pad formed therein;
providing a drill hole connected the first pad and the second pad; and
providing a third layer adjacent the second layer; and
cutting a void in the third layer corresponding to the second pad.

10. The method as claimed in claim 9, wherein the drill hole is a blind via.

11. The method as claimed in claim 10, wherein the first layer and the second layer are signal layers, and the third layer is anyone of a power layer and a ground layer.

12. The method as claimed in claim 9, wherein the drill hole is a buried via.

13. The method as claimed in claim 12, wherein a fourth layer is stacked between the first layer and the second layer, the drill hole passes through the first, second, and fourth layers, an annular antipad is formed in the fourth layer around the drill hole for insulating a conductive lining of the drill hole from the fourth layer.

14. The method as claimed in claim 13, wherein a fifth layer is stacked adjacent the first layer, an void is defined in the fifth layer corresponding to the first pad.

15. The method as claimed in claim 14, wherein the first and second layers are signal layers, and the third, fourth, and fifth layers are reference layers.
